(19) United States
(12) Patent Application Publication
(10) Pub. No.: US 2025/0238893 A1
(43) Pub. Date: Jul. 24, 2025

(54) AERIAL IMAGE GENERATION THROUGH PHYSICS-INFORMED KERNEL LEARNING

(71) Applicant: NVIDIA Corp., Santa Clara, CA (US)

(72) Inventors: Haoyu Yang, Round Rock, TX (US); Haoxing Ren, Austin, TX (US)

(73) Assignee: NVIDIA Corp., Santa Clara, CA (US)

(21) Appl. No.: 18/419,064

(22) Filed: Jan. 22, 2024

(51) Int. Cl. G06T 3/4046; G06F 30/33

(52) U.S. Cl. CPC G06T 3/4046; G06F 30/33

(57) ABSTRACT

A lithographic aerial image generator configured to transform a mask image of a circuit into light intensity feature maps, to bias the light intensity feature maps with lithographic optical physics weights to generate a coarse aerial image, and to transform the coarse aerial image through a first neural network to generate a lithographic-quality areal image.

### BACKGROUND

A major challenge in the field of lithography is the continued scaling of semiconductor manufacturing process technology to smaller dimensions and higher densities. One mechanism that may be utilized to this end is aerial image prediction from mask shapes.

Conventional optical and resist modelling involves design optimization loops, making efficient solutions time-intensive and computationally demanding. Due to improper biasing and/or configuration, conventional artificial intelligence mechanisms for aerial image prediction exhibit performance and accuracy limits that constrain their applicability to state-of-the-art lithography.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 depicts a process for creating a lithograph mask.

FIG. 2 depicts optical modeling and resist stages of lithographic modeling.

FIG. 3 depicts an embodiment of aerial image generation model incorporating optical physics effects.

FIG. 4 depicts a parallel processing unit 402 in accordance with one embodiment.

FIG. 5 depicts a general processing cluster 500 in accordance with one embodiment.

FIG. 6 depicts a memory partition unit 600 in accordance with one embodiment.

FIG. 7 depicts a streaming multiprocessor 700 in accordance with one embodiment.

FIG. 8 depicts a processing system 800 in accordance with one embodiment.

FIG. 9 depicts an exemplary processing system 900 in accordance with another embodiment.

FIG. 10 depicts a graphics processing pipeline 1000 in accordance with one embodiment.

### DETAILED DESCRIPTION

Embodiments of systems are disclosed that transform a mask image into a plurality of light intensity feature maps, weight the light intensity feature maps with lithographic optical physics bias to generate a coarse aerial image, and transform the coarse aerial image into a lithographic aerial image. The mask image is transformed through first neural network layer(s) into the light intensity feature maps, the light intensity feature maps are transformed into the coarse aerial image through second neural network layer(s), and the coarse aerial image is transformed into the lithographic aerial image through third neural network layer(s). The first network layer(s) may comprise at least one convolutional neural network layer and the third network layer(s) may comprise at least one transpose convolutional neural network layer.

The light intensity feature maps may be weighted with the lithographic optical physics bias in the frequency domain. During training of the overall model, a cost function may be applied to the generated lithographic aerial image and an ideal lithographic aerial image to train lithographic optical physics bias into the parameters of the first neural network layers, the second neural network layers, and the third neural network layers.

Other technical features may be readily apparent to one skilled in the art from the following figures, descriptions, and claims.

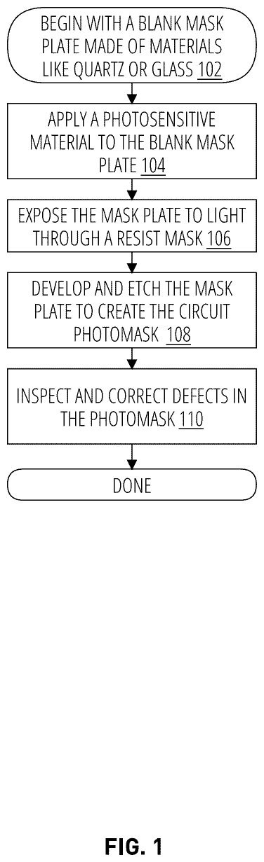

FIG. 1 depicts a process for creating a lithograph mask (photomask) in one embodiment. The process begins with a blank mask plate made of materials like quartz or glass (done block 102). In block 104, a photosensitive material is applied to the blank mask plate. In block 106, the mask plate is exposed to light through a resist mask embodying the final aerial image to project onto the silicon wafer. The aerial image is a physical pattern of light-passing and light-blocking/light-restricting shapes that embody the circuit structure to fabricate. In block 108, the mask plate is developed and etched to create the photomask. In block 110, the photomask is inspected and any defects are corrected, if possible.

The final lithography mask is used in conjunction with other semiconductor manufacturing processes, such as wafer photoresist coating, exposure, development, and etching, to transfer and manufacture the circuit pattern on the semiconductor wafer. The specifics of the lithography mask fabrication process vary depending on the technology and complexity of the circuit being manufactured. Various advanced techniques, including multiple patterning and resolution enhancement technologies, may also be employed to achieve smaller feature sizes and higher circuit densities.

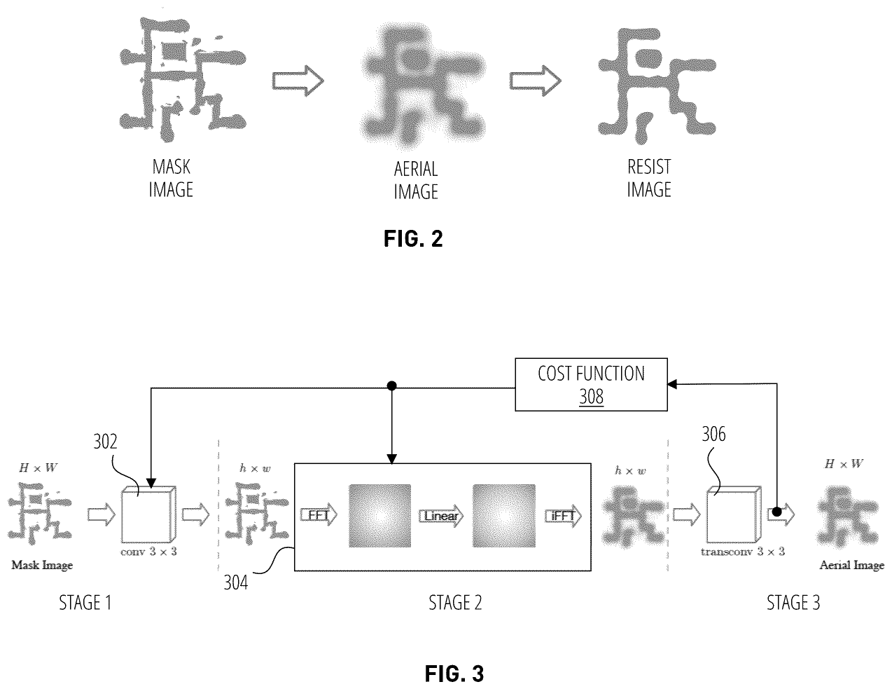

At a high level, lithography mask modeling and manufacture comprises optical modeling and resist stages as depicted in the example of FIG. 2. Optical modeling generates an aerial image of a circuit, and the resist stage transforms the aerial image into a aerial image to apply to the resist-coated mask plate. The optical modeling stage applies interactions between a lithography beam and the mask to generate a light intensity map comprising the aerial image. The resist modeling stage enhances the aerial image into a resist image that includes physical effects of light intensity on resist materials.

The process utilized in legacy mechanisms to generate the aerial image may be represented by

$$I = {\sum }_{i = 1}^{k} {α}_{i} {‖ M ⊗ {h}_{i} ‖}_{2}^{2} ,$$

where hi are optical kernels and αᵢ are coefficients associated with the optical kernels. M represents the mask image and I is the generated aerial image. The kernels are convolved across the receptive fields of the mask image and the resulting features are each scaled by a coefficient. The scaled features are combined into a light intensity feature map that constitutes the final aerial image I. In this conventional approach, the kernel parameters and/or discrete coefficients often require time-intensive manual tuning and adjustment to achieve the desired accuracy in the aerial image I.

FIG. 3 depicts an embodiment of aerial image generation model incorporating optical physics effects. The model generates lithographic-quality aerial images that may be utilized to generate resist masks for integrated circuit fabrication.

Stage 1 performs a spatial domain transformation of the original two-dimensional (2D) mask image having height H and width W, to generate a set of images each comprising a smaller-sized feature space of dimensions h×w, where h<<H and w<<W. The spatial domain transformation may be implemented in manners known in the art, including but not limited to convolution, batch normalization, ResNet, ReLU, and variations and combinations thereof. In one particular embodiment, as depicted in FIG. 3, a single convolutional neural network layer 302 comprising 3×3 kernels is utilized to perform the transformation to a lower-dimensional image in Stage 1. The kernels in this stage may utilize real-valued weights W₁ that are trained from initial values as described in more detail below.

Stage 2 of the model comprises layers to add inductive bias to the neural network to account for the physical effects of light intensity on resist material. Stage 2 applies optical physics biasing layers 304 on the lower-resolution images generated by Stage 1 to generate a low-resolution light intensity map biased with lithographic optical physics effects, as follows:

$${I}_{t} - {\sum }_{i = 1}^{k} {‖ {ℱ}^{- 1} ( ℱ ( M ) ⊙ {𝕎}_{2 , i} ) ‖}_{2}^{2} ,$$

where the kernel weights W_{2,i} for Stage 2 are generally complex valued and the Stage 2 kernels have size h×w. The complex-valued kernels in this stage are also evolved and reconfigured from their initial values via training. The inner term [symbol] (M)⊙Wᵢ is an element-wise (Hadamard) product of the FFT of the input mask image element values and the kernel weights. Stage 2 of the model obviates determination and use of the discrete coefficients utilized in conventional approaches.

The light intensity map Iₜ is a feature map (also herein, the “coarse aerial image”). This feature map is input at Stage 3 to subsequent network layers of the neural network. Stage 3 up-samples the light intensity features generated by Stage 2 into finer features with the dimensions H×W of the original input mask (herein the “fine aerial image”). Stage 3 may be implemented via transposed convolution layers with or without ResNet, batch normalization, ReLU, and other processing known in the art for such purposes. FIG. 3 depicts a particular embodiment utilizing a single transpose convolutional neural network layer 306 comprising 3×3 real-valued kernels. As with the weights in other stages, the weights W₃ in the transposed convolutional layers are also evolved and reconfigured via training.

The training objective across all three stages of the network is configured to minimize a difference between the generated fine aerial image I and a ground truth (“ideal”) aerial image I*. In one embodiment a common cost function 308 is utilized to configure (train) the kernels in all stages together, in effect biasing the weights of all layers to inductively adjust for optical effects on resist material. In one embodiment the cost function 308 may comprise a mean square error (MSE) function such as:

$$ℓ = {‖ I - I * ‖}_{2}^{2}$$

The cost function quantifies the model's performance against an ideal output and guides the configuration of the parameters in each stage. During training, the cost function calculates the discrepancy between the output of the model and the desired output. By minimizing the cost function, the performance of the model is improved over the course of training by reducing its output error.

Due to the very high densities involved in state-of-the-art circuits, even a single pixel error in the fine aerial image may be fatal to manufacturing the circuit. A max error may be configured for the generated aerial image quality:

$$err = \frac{max \vert I - I * \vert}{max I *}$$

where max I* is the value of the maximal element in the ideal image vector and maz|I−I*| is the value of the maximal element of the absolute difference vector determined by element-wise subtraction of the ideal aerial image from the coarse aerial image. The algorithm for the max error above is non-differentiable and cannot be readily integrated into a machine learning training process. To address this constraint, a dynamic cost function may be utilized and applied only at critical points in the image:

$${ℓ}_{ep} = {‖ I [ {I}_{err} > {I}_{th} ] - I * [ {I}_{err} > {I}_{th} ] ‖}_{2}^{2}$$

$${I}_{err} = \vert I - I * \vert$$

The above algorithm specifies that the loss is determined only at critical points (cp), which are image locations where per-pixel error (in the absolute difference vector Iₑᵣᵣ) exceeds a configured manufacturing tolerance Iₜₕ. This may significantly reduce the averaging-effect exhibited when applying conventional MSE loss. To correctly bias the transformation algorithm, a loss from the intermediate output of Stage 2 may be added to a final cost function:

$$ℓ = {‖ I [ {I}_{err} > {I}_{th} ] - I * [ {I}_{err} > {I}_{th} ] ‖}_{2}^{2} + {‖ {I}_{t} - I * ‖}_{2}^{2}$$

with W and Wₜ configured (trained) using conventional back-propagation.

The algorithms and techniques disclosed herein may be executed by computing devices utilizing one or more graphic processing unit (GPU) and/or general purpose data processor (e.g., a ‘central processing unit or CPU). Exemplary architectures will now be described that may be configured to carry out the techniques disclosed herein on such devices.

The following description may use certain acronyms and abbreviations as follows:
“DPC” refers to a “data processing cluster”;
“GPC” refers to a “general processing cluster”;
“I/O” refers to a “input/output”;
“L1 cache” refers to “level one cache”;
“L2 cache” refers to “level two cache”;
“LSU” refers to a “load/store unit”;
“MMU” refers to a “memory management unit”;
“MPC” refers to an “M-pipe controller”;
“PPU” refers to a “parallel processing unit”;
“PROP” refers to a “pre-raster operations unit”;
“ROP” refers to a “raster operations”;
“SFU” refers to a “special function unit”;
“SM” refers to a “streaming multiprocessor”;
“Viewport SCC” refers to “viewport scale, cull, and clip”;
“WDX” refers to a “work distribution crossbar”; and
“XBar” refers to a “crossbar”.

### Parallel Processing Unit

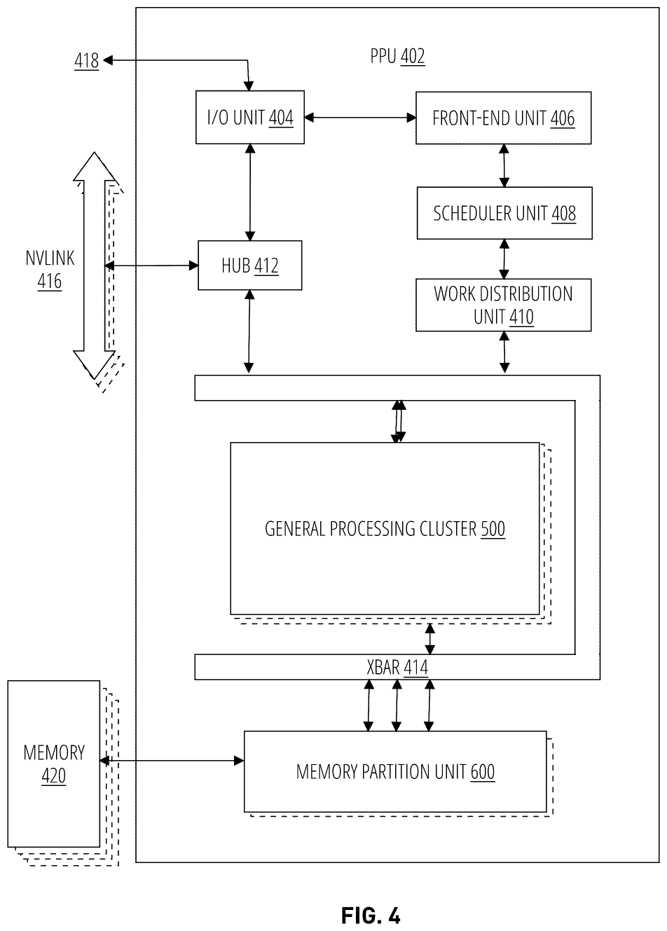

FIG. 4 depicts a parallel processing unit 402, in accordance with an embodiment. In an embodiment, the parallel processing unit 402 is a multi-threaded processor that is implemented on one or more integrated circuit devices. The parallel processing unit 402 is a latency hiding architecture designed to process many threads in parallel. A thread (e.g., a thread of execution) is an instantiation of a set of instructions configured to be executed by the parallel processing unit 402. In an embodiment, the parallel processing unit 402 is a graphics processing unit (GPU) configured to implement a graphics rendering pipeline for processing three-dimensional (3D) graphics data in order to generate two-dimensional (2D) image data for display on a display device such as a liquid crystal display (LCD) device. In other embodiments, the parallel processing unit 402 may be utilized for performing general-purpose computations. While one exemplary parallel processor is provided herein for illustrative purposes, it should be strongly noted that such processor is set forth for illustrative purposes only, and that any processor may be employed to supplement and/or substitute for the same.

One or more parallel processing unit 402 modules may be configured to accelerate thousands of High Performance Computing (HPC), data center, and machine learning applications. The parallel processing unit 402 may be configured to accelerate numerous deep learning systems and applications including autonomous vehicle platforms, deep learning, high-accuracy speech, image, and text recognition systems, intelligent video analytics, molecular simulations, drug discovery, disease diagnosis, weather forecasting, big data analytics, astronomy, molecular dynamics simulation, financial modeling, robotics, factory automation, real-time language translation, online search optimizations, and personalized user recommendations, and the like.

As shown in FIG. 4, the parallel processing unit 402 includes an I/O unit 404, a front-end unit 406, a scheduler unit 408, a work distribution unit 410, a hub 412, a crossbar 414, one or more general processing cluster 500 modules, and one or more memory partition unit 600 modules. The parallel processing unit 402 may be connected to a host processor or other parallel processing unit 402 modules via one or more high-speed NVLink 416 interconnects. The parallel processing unit 402 may be connected to a host processor or other peripheral devices via an interconnect 418. The parallel processing unit 402 may also be connected to a local memory comprising a number of memory 420 devices. In an embodiment, the local memory may comprise a number of dynamic random access memory (DRAM) devices. The DRAM devices may be configured as a high-bandwidth memory (HBM) subsystem, with multiple DRAM dies stacked within each device. The memory 420 may comprise logic to configure the parallel processing unit 402 to carry out aspects of the techniques disclosed herein.

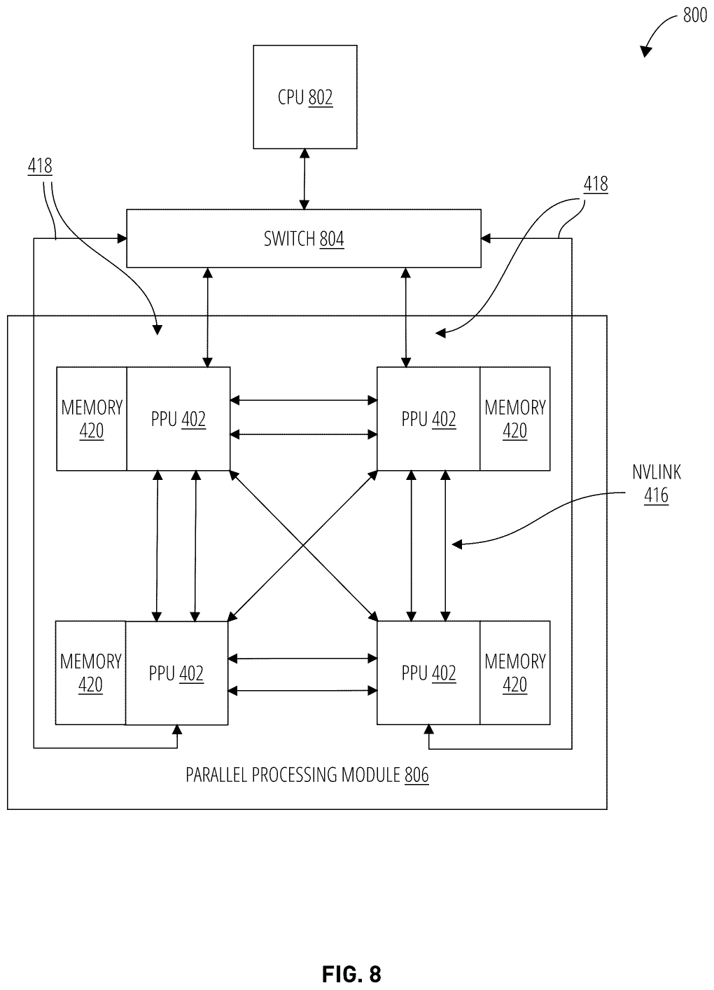

The NVLink 416 interconnect enables systems to scale and include one or more parallel processing unit 402 modules combined with one or more CPUs, supports cache coherence between the parallel processing unit 402 modules and CPUs, and CPU mastering. Data and/or commands may be transmitted by the NVLink 416 through the hub 412 to/from other units of the parallel processing unit 402 such as one or more copy engines, a video encoder, a video decoder, a power management unit, etc. (not explicitly shown). The NVLink 416 is described in more detail in conjunction with FIG. 8.

The I/O unit 404 is configured to transmit and receive communications (e.g., commands, data, etc.) from a host processor (not shown) over the interconnect 418. The I/O unit 404 may communicate with the host processor directly via the interconnect 418 or through one or more intermediate devices such as a memory bridge. In an embodiment, the I/O unit 404 may communicate with one or more other processors, such as one or more parallel processing unit 402 modules via the interconnect 418. In an embodiment, the I/O unit 404 implements a Peripheral Component Interconnect Express (PCIe) interface for communications over a PCIe bus and the interconnect 418 is a PCIe bus. In alternative embodiments, the I/O unit 404 may implement other types of well-known interfaces for communicating with external devices.

The I/O unit 404 decodes packets received via the interconnect 418. In an embodiment, the packets represent commands configured to cause the parallel processing unit 402 to perform various operations. The I/O unit 404 transmits the decoded commands to various other units of the parallel processing unit 402 as the commands may specify. For example, some commands may be transmitted to the front-end unit 406. Other commands may be transmitted to the hub 412 or other units of the parallel processing unit 402 such as one or more copy engines, a video encoder, a video decoder, a power management unit, etc. (not explicitly shown). In other words, the I/O unit 404 is configured to route communications between and among the various logical units of the parallel processing unit 402.

In an embodiment, a program executed by the host processor encodes a command stream in a buffer that provides workloads to the parallel processing unit 402 for processing. A workload may comprise several instructions and data to be processed by those instructions. The buffer is a region in a memory that is accessible (e.g., read/write) by both the host processor and the parallel processing unit 402. For example, the I/O unit 404 may be configured to access the buffer in a system memory connected to the interconnect 418 via memory requests transmitted over the interconnect 418. In an embodiment, the host processor writes the command stream to the buffer and then transmits a pointer to the start of the command stream to the parallel processing unit 402. The front-end unit 406 receives pointers to one or more command streams. The front-end unit 406 manages the one or more streams, reading commands from the streams and forwarding commands to the various units of the parallel processing unit 402.

The front-end unit 406 is coupled to a scheduler unit 408 that configures the various general processing cluster 500 modules to process tasks defined by the one or more streams. The scheduler unit 408 is configured to track state information related to the various tasks managed by the scheduler unit 408. The state may indicate which general processing cluster 500 a task is assigned to, whether the task is active or inactive, a priority level associated with the task, and so forth. The scheduler unit 408 manages the execution of a plurality of tasks on the one or more general processing cluster 500 modules.

The scheduler unit 408 is coupled to a work distribution unit 410 that is configured to dispatch tasks for execution on the general processing cluster 500 modules. The work distribution unit 410 may track a number of scheduled tasks received from the scheduler unit 408. In an embodiment, the work distribution unit 410 manages a pending task pool and an active task pool for each of the general processing cluster 500 modules. The pending task pool may comprise a number of slots (e.g., 32 slots) that contain tasks assigned to be processed by a particular general processing cluster 500. The active task pool may comprise a number of slots (e.g., 4 slots) for tasks that are actively being processed by the general processing cluster 500 modules. As a general processing cluster 500 finishes the execution of a task, that task is evicted from the active task pool for the general processing cluster 500 and one of the other tasks from the pending task pool is selected and scheduled for execution on the general processing cluster 500. If an active task has been idle on the general processing cluster 500, such as while waiting for a data dependency to be resolved, then the active task may be evicted from the general processing cluster 500 and returned to the pending task pool while another task in the pending task pool is selected and scheduled for execution on the general processing cluster 500.

The work distribution unit 410 communicates with the one or more general processing cluster 500 modules via crossbar 414. The crossbar 414 is an interconnect network that couples many of the units of the parallel processing unit 402 to other units of the parallel processing unit 402. For example, the crossbar 414 may be configured to couple the work distribution unit 410 to a particular general processing cluster 500. Although not shown explicitly, one or more other units of the parallel processing unit 402 may also be connected to the crossbar 414 via the hub 412.

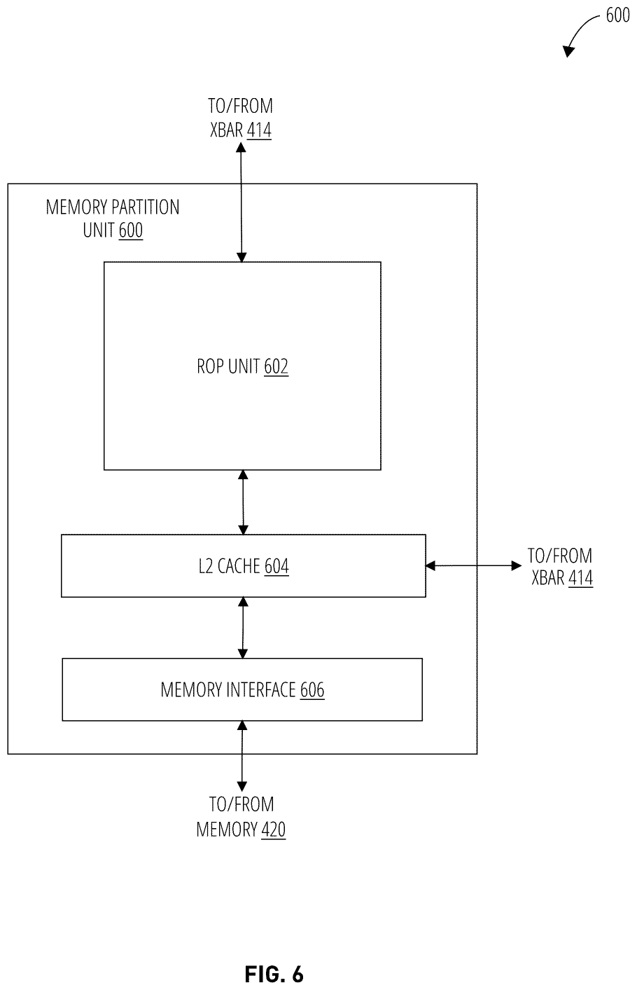

The tasks are managed by the scheduler unit 408 and dispatched to a general processing cluster 500 by the work distribution unit 410. The general processing cluster 500 is configured to process the task and generate results. The results may be consumed by other tasks within the general processing cluster 500, routed to a different general processing cluster 500 via the crossbar 414, or stored in the memory 420. The results can be written to the memory 420 via the memory partition unit 600 modules, which implement a memory interface for reading and writing data to/from the memory 420. The results can be transmitted to another parallel processing unit 402 or CPU via the NVLink 416. In an embodiment, the parallel processing unit 402 includes a number U of memory partition unit 600 modules that is equal to the number of separate and distinct memory 420 devices coupled to the parallel processing unit 402. A memory partition unit 600 will be described in more detail below in conjunction with FIG. 6.

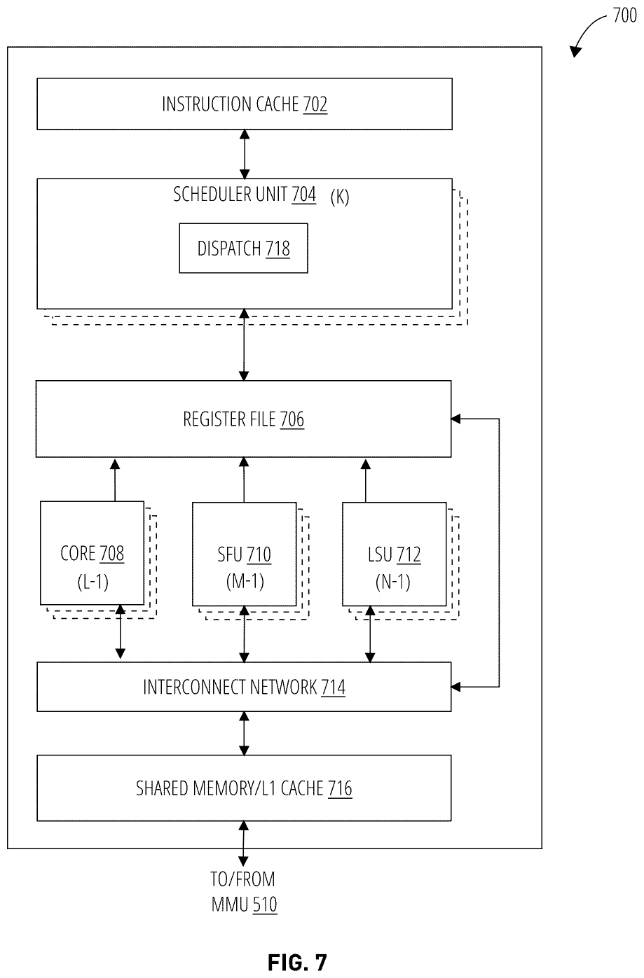

In an embodiment, a host processor executes a driver kernel that implements an application programming interface (API) that enables one or more applications executing on the host processor to schedule operations for execution on the parallel processing unit 402. In an embodiment, multiple compute applications are simultaneously executed by the parallel processing unit 402 and the parallel processing unit 402 provides isolation, quality of service (QoS), and independent address spaces for the multiple compute applications. An application may generate instructions (e.g., API calls) that cause the driver kernel to generate one or more tasks for execution by the parallel processing unit 402. The driver kernel outputs tasks to one or more streams being processed by the parallel processing unit 402. Each task may comprise one or more groups of related threads, referred to herein as a warp. In an embodiment, a warp comprises 32 related threads that may be executed in parallel. Cooperating threads may refer to a plurality of threads including instructions to perform the task and that may exchange data through shared memory. Threads and cooperating threads are described in more detail in conjunction with FIG. 7.

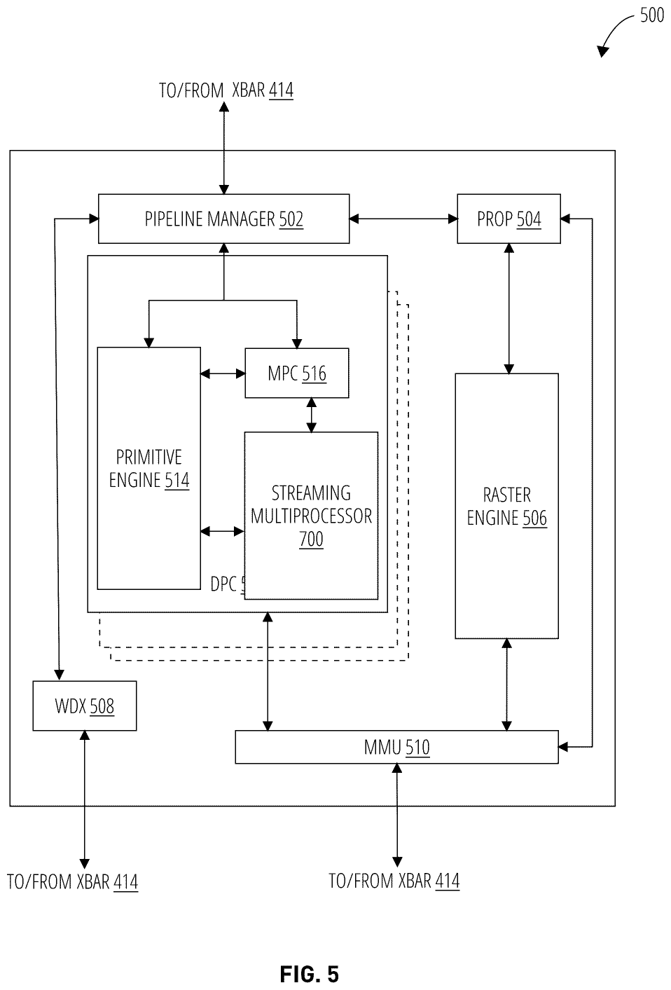

FIG. 5 depicts a general processing cluster 500 of the parallel processing unit 402 of FIG. 4, in accordance with an embodiment. As shown in FIG. 5, each general processing cluster 500 includes a number of hardware units for processing tasks. In an embodiment, each general processing cluster 500 includes a pipeline manager 502, a pre-raster operations unit 504, a raster engine 506, a work distribution crossbar 508, a memory management unit 510, and one or more data processing cluster 512. It will be appreciated that the general processing cluster 500 of FIG. 5 may include other hardware units in lieu of or in addition to the units shown in FIG. 5.

In an embodiment, the operation of the general processing cluster 500 is controlled by the pipeline manager 502. The pipeline manager 502 manages the configuration of the one or more data processing cluster 512 modules for processing tasks allocated to the general processing cluster 500. In an embodiment, the pipeline manager 502 may configure at least one of the one or more data processing cluster 512 modules to implement at least a portion of a graphics rendering pipeline. For example, a data processing cluster 512 may be configured to execute a vertex shader program on the programmable streaming multiprocessor 700. The pipeline manager 502 may also be configured to route packets received from the work distribution unit 410 to the appropriate logical units within the general processing cluster 500. For example, some packets may be routed to fixed function hardware units in the pre-raster operations unit 504 and/or raster engine 506 while other packets may be routed to the data processing cluster 512 modules for processing by the primitive engine 514 or the streaming multiprocessor 700. In an embodiment, the pipeline manager 502 may configure at least one of the one or more data processing cluster 512 modules to implement a neural network model and/or a computing pipeline.

The pre-raster operations unit 504 is configured to route data generated by the raster engine 506 and the data processing cluster 512 modules to a Raster Operations (ROP) unit, described in more detail in conjunction with FIG. 6. The pre-raster operations unit 504 may also be configured to perform optimizations for color blending, organize pixel data, perform address translations, and the like.

The raster engine 506 includes a number of fixed function hardware units configured to perform various raster operations. In an embodiment, the raster engine 506 includes a setup engine, a coarse raster engine, a culling engine, a clipping engine, a fine raster engine, and a tile coalescing engine. The setup engine receives transformed vertices and generates plane equations associated with the geometric primitive defined by the vertices. The plane equations are transmitted to the coarse raster engine to generate coverage information (e.g., an x, y coverage mask for a tile) for the primitive. The output of the coarse raster engine is transmitted to the culling engine where fragments associated with the primitive that fail a z-test are culled, and transmitted to a clipping engine where fragments lying outside a viewing frustum are clipped. Those fragments that survive clipping and culling may be passed to the fine raster engine to generate attributes for the pixel fragments based on the plane equations generated by the setup engine. The output of the raster engine 506 comprises fragments to be processed, for example, by a fragment shader implemented within a data processing cluster 512.

Each data processing cluster 512 included in the general processing cluster 500 includes an M-pipe controller 516, a primitive engine 514, and one or more streaming multiprocessor 700 modules. The M-pipe controller 516 controls the operation of the data processing cluster 512, routing packets received from the pipeline manager 502 to the appropriate units in the data processing cluster 512. For example, packets associated with a vertex may be routed to the primitive engine 514, which is configured to fetch vertex attributes associated with the vertex from the memory 420. In contrast, packets associated with a shader program may be transmitted to the streaming multiprocessor 700.

The streaming multiprocessor 700 comprises a programmable streaming processor that is configured to process tasks represented by a number of threads. Each streaming multiprocessor 700 is multi-threaded and configured to execute a plurality of threads (e.g., 32 threads) from a particular group of threads concurrently. In an embodiment, the streaming multiprocessor 700 implements a Single-Instruction, Multiple-Data (SIMD) architecture where each thread in a group of threads (e.g., a warp) is configured to process a different set of data based on the same set of instructions. All threads in the group of threads execute the same instructions. In another embodiment, the streaming multiprocessor 700 implements a Single-Instruction, Multiple Thread (SIMT) architecture where each thread in a group of threads is configured to process a different set of data based on the same set of instructions, but where individual threads in the group of threads are allowed to diverge during execution. In an embodiment, a program counter, call stack, and execution state is maintained for each warp, enabling concurrency between warps and serial execution within warps when threads within the warp diverge. In another embodiment, a program counter, call stack, and execution state is maintained for each individual thread, enabling equal concurrency between all threads, within and between warps. When execution state is maintained for each individual thread, threads executing the same instructions may be converged and executed in parallel for maximum efficiency. The streaming multiprocessor 700 will be described in more detail below in conjunction with FIG. 7.

The memory management unit 510 provides an interface between the general processing cluster 500 and the memory partition unit 600. The memory management unit 510 may provide translation of virtual addresses into physical addresses, memory protection, and arbitration of memory requests. In an embodiment, the memory management unit 510 provides one or more translation lookaside buffers (TLBs) for performing translation of virtual addresses into physical addresses in the memory 420.

FIG. 6 depicts a memory partition unit 600 of the parallel processing unit 402 of FIG. 4, in accordance with an embodiment. As shown in FIG. 6, the memory partition unit 600 includes a raster operations unit 602, a level two cache 604, and a memory interface 606. The memory interface 606 is coupled to the memory 420. Memory interface 606 may implement 32, 64, 128, 1024-bit data buses, or the like, for high-speed data transfer. In an embodiment, the parallel processing unit 402 incorporates U memory interface 606 modules, one memory interface 606 per pair of memory partition unit 600 modules, where each pair of memory partition unit 600 modules is connected to a corresponding memory 420 device. For example, parallel processing unit 402 may be connected to up to Y memory 420 devices, such as high bandwidth memory stacks or graphics double-data-rate, version 5, synchronous dynamic random access memory, or other types of persistent storage.

In an embodiment, the memory interface 606 implements an HBM2 memory interface and Y equals half U. In an embodiment, the HBM2 memory stacks are located on the same physical package as the parallel processing unit 402, providing substantial power and area savings compared with conventional GDDR5 SDRAM systems. In an embodiment, each HBM2 stack includes four memory dies and Y equals 4, with HBM2 stack including two 128-bit channels per die for a total of 8 channels and a data bus width of 1024 bits.

In an embodiment, the memory 420 supports Single-Error Correcting Double-Error Detecting (SECDED) Error Correction Code (ECC) to protect data. ECC provides higher reliability for compute applications that are sensitive to data corruption. Reliability is especially important in large-scale cluster computing environments where parallel processing unit 402 modules process very large datasets and/or run applications for extended periods.

In an embodiment, the parallel processing unit 402 implements a multi-level memory hierarchy. In an embodiment, the memory partition unit 600 supports a unified memory to provide a single unified virtual address space for CPU and parallel processing unit 402 memory, enabling data sharing between virtual memory systems. In an embodiment the frequency of accesses by a parallel processing unit 402 to memory located on other processors is traced to ensure that memory pages are moved to the physical memory of the parallel processing unit 402 that is accessing the pages more frequently. In an embodiment, the NVLink 416 supports address translation services allowing the parallel processing unit 402 to directly access a CPU's page tables and providing full access to CPU memory by the parallel processing unit 402.

In an embodiment, copy engines transfer data between multiple parallel processing unit 402 modules or between parallel processing unit 402 modules and CPUs. The copy engines can generate page faults for addresses that are not mapped into the page tables. The memory partition unit 600 can then service the page faults, mapping the addresses into the page table, after which the copy engine can perform the transfer. In a conventional system, memory is pinned (e.g., non-pageable) for multiple copy engine operations between multiple processors, substantially reducing the available memory. With hardware page faulting, addresses can be passed to the copy engines without worrying if the memory pages are resident, and the copy process is transparent.

Data from the memory 420 or other system memory may be fetched by the memory partition unit 600 and stored in the level two cache 604, which is located on-chip and is shared between the various general processing cluster 500 modules. As shown, each memory partition unit 600 includes a portion of the level two cache 604 associated with a corresponding memory 420 device. Lower level caches may then be implemented in various units within the general processing cluster 500 modules. For example, each of the streaming multiprocessor 700 modules may implement an L1 cache. The L1 cache is private memory that is dedicated to a particular streaming multiprocessor 700. Data from the level two cache 604 may be fetched and stored in each of the L1 caches for processing in the functional units of the streaming multiprocessor 700 modules. The level two cache 604 is coupled to the memory interface 606 and the crossbar 414.

The raster operations unit 602 performs graphics raster operations related to pixel color, such as color compression, pixel blending, and the like. The raster operations unit 602 also implements depth testing in conjunction with the raster engine 506, receiving a depth for a sample location associated with a pixel fragment from the culling engine of the raster engine 506. The depth is tested against a corresponding depth in a depth buffer for a sample location associated with the fragment. If the fragment passes the depth test for the sample location, then the raster operations unit 602 updates the depth buffer and transmits a result of the depth test to the raster engine 506. It will be appreciated that the number of partition memory partition unit 600 modules may be different than the number of general processing cluster 500 modules and, therefore, each raster operations unit 602 may be coupled to each of the general processing cluster 500 modules. The raster operations unit 602 tracks packets received from the different general processing cluster 500 modules and determines which general processing cluster 500 that a result generated by the raster operations unit 602 is routed to through the crossbar 414. Although the raster operations unit 602 is included within the memory partition unit 600 in FIG. 6, in other embodiment, the raster operations unit 602 may be outside of the memory partition unit 600. For example, the raster operations unit 602 may reside in the general processing cluster 500 or another unit.

FIG. 7 illustrates the streaming multiprocessor 700 of FIG. 5, in accordance with an embodiment. As shown in FIG. 7, the streaming multiprocessor 700 includes an instruction cache 702, one or more scheduler unit 704 modules (e.g., such as scheduler unit 408), a register file 706, one or more processing core 708 modules, one or more special function unit 710 modules, one or more load/store unit 712 modules, an interconnect network 714, and a shared memory/L1 cache 716.

As described above, the work distribution unit 410 dispatches tasks for execution on the general processing cluster 500 modules of the parallel processing unit 402. The tasks are allocated to a particular data processing cluster 512 within a general processing cluster 500 and, if the task is associated with a shader program, the task may be allocated to a streaming multiprocessor 700. The scheduler unit 408 receives the tasks from the work distribution unit 410 and manages instruction scheduling for one or more thread blocks assigned to the streaming multiprocessor 700. The scheduler unit 704 schedules thread blocks for execution as warps of parallel threads, where each thread block is allocated at least one warp. In an embodiment, each warp executes 32 threads. The scheduler unit 704 may manage a plurality of different thread blocks, allocating the warps to the different thread blocks and then dispatching instructions from the plurality of different cooperative groups to the various functional units (e.g., core 708 modules, special function unit 710 modules, and load/store unit 712 modules) during each clock cycle.

Cooperative Groups is a programming model for organizing groups of communicating threads that allows developers to express the granularity at which threads are communicating, enabling the expression of richer, more efficient parallel decompositions. Cooperative launch APIs support synchronization amongst thread blocks for the execution of parallel algorithms. Conventional programming models provide a single, simple construct for synchronizing cooperating threads: a barrier across all threads of a thread block (e.g., the syncthreads( ) function). However, programmers would often like to define groups of threads at smaller than thread block granularities and synchronize within the defined groups to enable greater performance, design flexibility, and software reuse in the form of collective group-wide function interfaces.

Cooperative Groups enables programmers to define groups of threads explicitly at sub-block (e.g., as small as a single thread) and multi-block granularities, and to perform collective operations such as synchronization on the threads in a cooperative group. The programming model supports clean composition across software boundaries, so that libraries and utility functions can synchronize safely within their local context without having to make assumptions about convergence. Cooperative Groups primitives enable new patterns of cooperative parallelism, including producer-consumer parallelism, opportunistic parallelism, and global synchronization across an entire grid of thread blocks.

A dispatch 718 unit is configured within the scheduler unit 704 to transmit instructions to one or more of the functional units. In one embodiment, the scheduler unit 704 includes two dispatch 718 units that enable two different instructions from the same warp to be dispatched during each clock cycle. In alternative embodiments, each scheduler unit 704 may include a single dispatch 718 unit or additional dispatch 718 units.

Each streaming multiprocessor 700 includes a register file 706 that provides a set of registers for the functional units of the streaming multiprocessor 700. In an embodiment, the register file 706 is divided between each of the functional units such that each functional unit is allocated a dedicated portion of the register file 706. In another embodiment, the register file 706 is divided between the different warps being executed by the streaming multiprocessor 700. The register file 706 provides temporary storage for operands connected to the data paths of the functional units.

Each streaming multiprocessor 700 comprises L processing core 708 modules. In an embodiment, the streaming multiprocessor 700 includes a large number (e.g., 128, etc.) of distinct processing core 708 modules. Each core 708 may include a fully-pipelined, single-precision, double-precision, and/or mixed precision processing unit that includes a floating point arithmetic logic unit and an integer arithmetic logic unit. In an embodiment, the floating point arithmetic logic units implement the IEEE 754-2008 standard for floating point arithmetic. In an embodiment, the core 708 modules include 64 single-precision (32-bit) floating point cores, 64 integer cores, 32 double-precision (64-bit) floating point cores, and 8 tensor cores.

Tensor cores configured to perform matrix operations, and, in an embodiment, one or more tensor cores are included in the core 708 modules. In particular, the tensor cores are configured to perform deep learning matrix arithmetic, such as convolution operations for neural network training and inferencing. In an embodiment, each tensor core operates on a 4×4 matrix and performs a matrix multiply and accumulate operation D=A′B+C, where A, B, C, and D are 4×4 matrices.

In an embodiment, the matrix multiply inputs A and B are 16-bit floating point matrices, while the accumulation matrices C and D may be 16-bit floating point or 32-bit floating point matrices. Tensor Cores operate on 16-bit floating point input data with 32-bit floating point accumulation. The 16-bit floating point multiply requires 64 operations and results in a full precision product that is then accumulated using 32-bit floating point addition with the other intermediate products for a 4×4×4 matrix multiply. In practice, Tensor Cores are used to perform much larger two-dimensional or higher dimensional matrix operations, built up from these smaller elements. An API, such as CUDA 9 C++ API, exposes specialized matrix load, matrix multiply and accumulate, and matrix store operations to efficiently use Tensor Cores from a CUDA-C++ program. At the CUDA level, the warp-level interface assumes 16×16 size matrices spanning all 32 threads of the warp.

Each streaming multiprocessor 700 also comprises M special function unit 710 modules that perform special functions (e.g., attribute evaluation, reciprocal square root, and the like). In an embodiment, the special function unit 710 modules may include a tree traversal unit configured to traverse a hierarchical tree data structure. In an embodiment, the special function unit 710 modules may include texture unit configured to perform texture map filtering operations. In an embodiment, the texture units are configured to load texture maps (e.g., a 2D array of texels) from the memory 420 and sample the texture maps to produce sampled texture values for use in shader programs executed by the streaming multiprocessor 700. In an embodiment, the texture maps are stored in the shared memory/L1 cache 716. The texture units implement texture operations such as filtering operations using mip-maps (e.g., texture maps of varying levels of detail). In an embodiment, each streaming multiprocessor 700 includes two texture units.

Each streaming multiprocessor 700 also comprises N load/store unit 712 modules that implement load and store operations between the shared memory/L1 cache 716 and the register file 706. Each streaming multiprocessor 700 includes an interconnect network 714 that connects each of the functional units to the register file 706 and the load/store unit 712 to the register file 706 and shared memory/L1 cache 716. In an embodiment, the interconnect network 714 is a crossbar that can be configured to connect any of the functional units to any of the registers in the register file 706 and connect the load/store unit 712 modules to the register file 706 and memory locations in shared memory/L1 cache 716.

The shared memory/L1 cache 716 is an array of on-chip memory that allows for data storage and communication between the streaming multiprocessor 700 and the primitive engine 514 and between threads in the streaming multiprocessor 700. In an embodiment, the shared memory/L1 cache 716 comprises 128 KB of storage capacity and is in the path from the streaming multiprocessor 700 to the memory partition unit 600. The shared memory/L1 cache 716 can be used to cache reads and writes. One or more of the shared memory/L1 cache 716, level two cache 604, and memory 420 are backing stores.

Combining data cache and shared memory functionality into a single memory block provides the best overall performance for both types of memory accesses. The capacity is usable as a cache by programs that do not use shared memory. For example, if shared memory is configured to use half of the capacity, texture and load/store operations can use the remaining capacity. Integration within the shared memory/L1 cache 716 enables the shared memory/L1 cache 716 to function as a high-throughput conduit for streaming data while simultaneously providing high-bandwidth and low-latency access to frequently reused data.

When configured for general purpose parallel computation, a simpler configuration can be used compared with graphics processing. Specifically, the fixed function graphics processing units shown in FIG. 4, are bypassed, creating a much simpler programming model. In the general purpose parallel computation configuration, the work distribution unit 410 assigns and distributes blocks of threads directly to the data processing cluster 512 modules. The threads in a block execute the same program, using a unique thread ID in the calculation to ensure each thread generates unique results, using the streaming multiprocessor 700 to execute the program and perform calculations, shared memory/L1 cache 716 to communicate between threads, and the load/store unit 712 to read and write global memory through the shared memory/L1 cache 716 and the memory partition unit 600. When configured for general purpose parallel computation, the streaming multiprocessor 700 can also write commands that the scheduler unit 408 can use to launch new work on the data processing cluster 512 modules.

The parallel processing unit 402 may be included in a desktop computer, a laptop computer, a tablet computer, servers, supercomputers, a smart-phone (e.g., a wireless, hand-held device), personal digital assistant (PDA), a digital camera, a vehicle, a head mounted display, a hand-held electronic device, and the like. In an embodiment, the parallel processing unit 402 is embodied on a single semiconductor substrate. In another embodiment, the parallel processing unit 402 is included in a system-on-a-chip (SoC) along with one or more other devices such as additional parallel processing unit 402 modules, the memory 420, a reduced instruction set computer (RISC) CPU, a memory management unit (MMU), a digital-to-analog converter (DAC), and the like.

In an embodiment, the parallel processing unit 402 may be included on a graphics card that includes one or more memory devices. The graphics card may be configured to interface with a PCIe slot on a motherboard of a desktop computer. In yet another embodiment, the parallel processing unit 402 may be an integrated graphics processing unit (iGPU) or parallel processor included in the chipset of the motherboard.

### Exemplary Computing System

Systems with multiple GPUs and CPUs are used in a variety of industries as developers expose and leverage more parallelism in applications such as artificial intelligence computing. High-performance GPU-accelerated systems with tens to many thousands of compute nodes are deployed in data centers, research facilities, and supercomputers to solve ever larger problems. As the number of processing devices within the high-performance systems increases, the communication and data transfer mechanisms need to scale to support the increased bandwidth.

FIG. 8 is a conceptual diagram of a processing system 800 implemented using the parallel processing unit 402 of FIG. 4, in accordance with an embodiment. The processing system 800 includes a central processing unit 802, switch 804, and multiple parallel processing unit 402 modules each and respective memory 420 modules. The NVLink 416 provides high-speed communication links between each of the parallel processing unit 402 modules. Although a particular number of NVLink 416 and interconnect 418 connections are illustrated in FIG. 8, the number of connections to each parallel processing unit 402 and the central processing unit 802 may vary. The switch 804 interfaces between the interconnect 418 and the central processing unit 802. The parallel processing unit 402 modules, memory 420 modules, and NVLink 416 connections may be situated on a single semiconductor platform to form a parallel processing module 806. In an embodiment, the switch 804 supports two or more protocols to interface between various different connections and/or links.

In another embodiment (not shown), the NVLink 416 provides one or more high-speed communication links between each of the parallel processing unit modules (parallel processing unit 402, parallel processing unit 402, parallel processing unit 402, and parallel processing unit 402) and the central processing unit 802 and the switch 804 interfaces between the interconnect 418 and each of the parallel processing unit modules. The parallel processing unit modules, memory 420 modules, and interconnect 418 may be situated on a single semiconductor platform to form a parallel processing module 806. In yet another embodiment (not shown), the interconnect 418 provides one or more communication links between each of the parallel processing unit modules and the central processing unit 802 and the switch 804 interfaces between each of the parallel processing unit modules using the NVLink 416 to provide one or more high-speed communication links between the parallel processing unit modules. In another embodiment (not shown), the NVLink 416 provides one or more high-speed communication links between the parallel processing unit modules and the central processing unit 802 through the switch 804. In yet another embodiment (not shown), the interconnect 418 provides one or more communication links between each of the parallel processing unit modules directly. One or more of the NVLink 416 high-speed communication links may be implemented as a physical NVLink interconnect or either an on-chip or on-die interconnect using the same protocol as the NVLink 416.

In the context of the present description, a single semiconductor platform may refer to a sole unitary semiconductor-based integrated circuit fabricated on a die or chip. It should be noted that the term single semiconductor platform may also refer to multi-chip modules with increased connectivity which simulate on-chip operation and make substantial improvements over utilizing a conventional bus implementation. Of course, the various circuits or devices may also be situated separately or in various combinations of semiconductor platforms per the desires of the user. Alternately, the parallel processing module 806 may be implemented as a circuit board substrate and each of the parallel processing unit modules and/or memory 420 modules may be packaged devices. In an embodiment, the central processing unit 802, switch 804, and the parallel processing module 806 are situated on a single semiconductor platform.

In an embodiment, the signaling rate of each NVLink 416 is 20 to 25 Gigabits/second and each parallel processing unit module includes six NVLink 416 interfaces (as shown in FIG. 8, five NVLink 416 interfaces are included for each parallel processing unit module). Each NVLink 416 provides a data transfer rate of 25 Gigabytes/second in each direction, with six links providing 300 Gigabytes/second. The NVLink 416 can be used exclusively for PPU-to-PPU communication as shown in FIG. 8, or some combination of PPU-to-PPU and PPU-to-CPU, when the central processing unit 802 also includes one or more NVLink 416 interfaces.

In an embodiment, the NVLink 416 allows direct load/store/atomic access from the central processing unit 802 to each parallel processing unit module's memory 420. In an embodiment, the NVLink 416 supports coherency operations, allowing data read from the memory 420 modules to be stored in the cache hierarchy of the central processing unit 802, reducing cache access latency for the central processing unit 802. In an embodiment, the NVLink 416 includes support for Address Translation Services (ATS), enabling the parallel processing unit module to directly access page tables within the central processing unit 802. One or more of the NVLink 416 may also be configured to operate in a low-power mode.

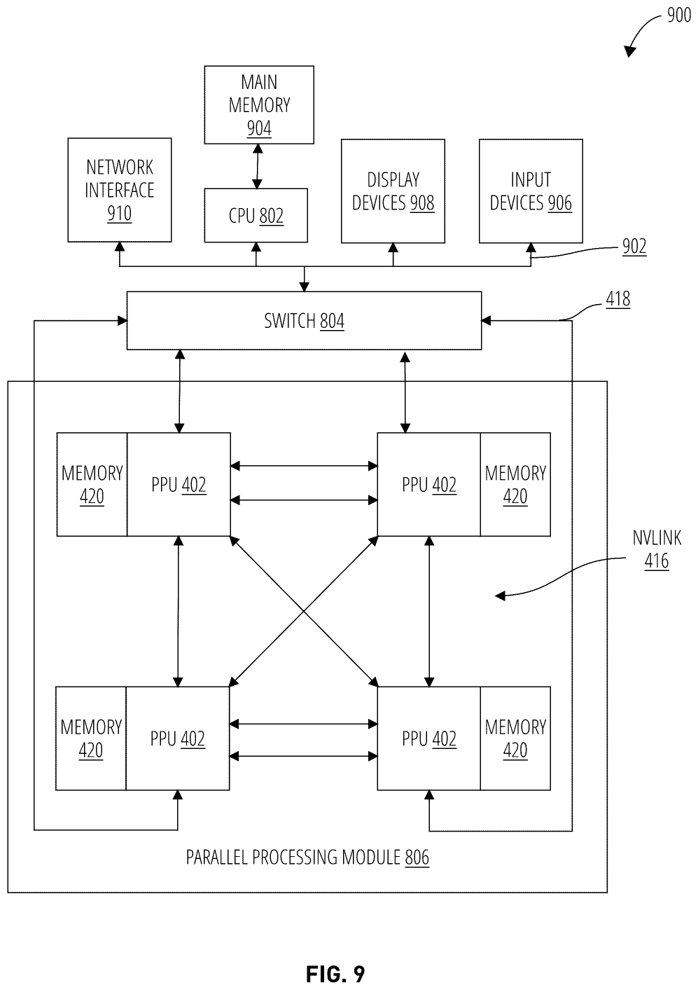

FIG. 9 depicts an exemplary processing system 900 in which the various architecture and/or functionality of the various previous embodiments may be implemented. As shown, an exemplary processing system 900 is provided including at least one central processing unit 802 that is connected to a communications bus 902. The communication communications bus 902 may be implemented using any suitable protocol, such as PCI (Peripheral Component Interconnect), PCI-Express, AGP (Accelerated Graphics Port), HyperTransport, or any other bus or point-to-point communication protocol(s). The exemplary processing system 900 also includes a main memory 904. Control logic (software) and data are stored in the main memory 904 which may take the form of random access memory (RAM).

The exemplary processing system 900 also includes input devices 906, the parallel processing module 806, and display devices 908, e.g. a conventional CRT (cathode ray tube), LCD (liquid crystal display), LED (light emitting diode), plasma display or the like. User input may be received from the input devices 906, e.g., keyboard, mouse, touchpad, microphone, and the like. Each of the foregoing modules and/or devices may even be situated on a single semiconductor platform to form the exemplary processing system 900. Alternately, the various modules may also be situated separately or in various combinations of semiconductor platforms per the desires of the user.

Further, the exemplary processing system 900 may be coupled to a network (e.g., a telecommunications network, local area network (LAN), wireless network, wide area network (WAN) such as the Internet, peer-to-peer network, cable network, or the like) through a network interface 910 for communication purposes.

The exemplary processing system 900 may also include a secondary storage (not shown). The secondary storage includes, for example, a hard disk drive and/or a removable storage drive, representing a floppy disk drive, a magnetic tape drive, a compact disk drive, digital versatile disk (DVD) drive, recording device, universal serial bus (USB) flash memory. The removable storage drive reads from and/or writes to a removable storage unit in a well-known manner.

Computer programs, or computer control logic algorithms, may be stored in the main memory 904 and/or the secondary storage. Such computer programs, when executed, enable the exemplary processing system 900 to perform various functions. The main memory 904, the storage, and/or any other storage are possible examples of computer-readable media.

The architecture and/or functionality of the various previous figures may be implemented in the context of a general computer system, a circuit board system, a game console system dedicated for entertainment purposes, an application-specific system, and/or any other desired system. For example, the exemplary processing system 900 may take the form of a desktop computer, a laptop computer, a tablet computer, servers, supercomputers, a smart-phone (e.g., a wireless, hand-held device), personal digital assistant (PDA), a digital camera, a vehicle, a head mounted display, a hand-held electronic device, a mobile phone device, a television, workstation, game consoles, embedded system, and/or any other type of logic.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

### Graphics Processing Pipeline

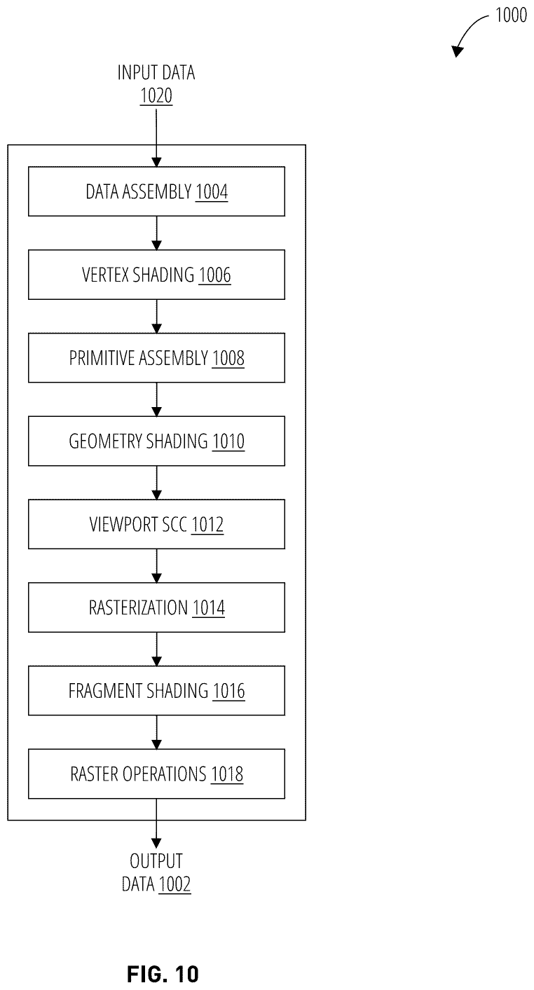

FIG. 10 is a conceptual diagram of a graphics processing pipeline 1000 implemented by the parallel processing unit 402 of FIG. 4, in accordance with an embodiment. In an embodiment, the parallel processing unit 402 comprises a graphics processing unit (GPU). The parallel processing unit 402 is configured to receive commands that specify shader programs for processing graphics data. Graphics data may be defined as a set of primitives such as points, lines, triangles, quads, triangle strips, and the like. Typically, a primitive includes data that specifies a number of vertices for the primitive (e.g., in a model-space coordinate system) as well as attributes associated with each vertex of the primitive. The parallel processing unit 402 can be configured to process the graphics primitives to generate a frame buffer (e.g., pixel data for each of the pixels of the display).

An application writes model data for a scene (e.g., a collection of vertices and attributes) to a memory such as a system memory or memory 420. The model data defines each of the objects that may be visible on a display. The application then makes an API call to the driver kernel that requests the model data to be rendered and displayed. The driver kernel reads the model data and writes commands to the one or more streams to perform operations to process the model data. The commands may reference different shader programs to be implemented on the streaming multiprocessor 700 modules of the parallel processing unit 402 including one or more of a vertex shader, hull shader, domain shader, geometry shader, and a pixel shader. For example, one or more of the streaming multiprocessor 700 modules may be configured to execute a vertex shader program that processes a number of vertices defined by the model data. In an embodiment, the different streaming multiprocessor 700 modules may be configured to execute different shader programs concurrently. For example, a first subset of streaming multiprocessor 700 modules may be configured to execute a vertex shader program while a second subset of streaming multiprocessor 700 modules may be configured to execute a pixel shader program. The first subset of streaming multiprocessor 700 modules processes vertex data to produce processed vertex data and writes the processed vertex data to the level two cache 604 and/or the memory 420. After the processed vertex data is rasterized (e.g., transformed from three-dimensional data into two-dimensional data in screen space) to produce fragment data, the second subset of streaming multiprocessor 700 modules executes a pixel shader to produce processed fragment data, which is then blended with other processed fragment data and written to the frame buffer in memory 420. The vertex shader program and pixel shader program may execute concurrently, processing different data from the same scene in a pipelined fashion until all of the model data for the scene has been rendered to the frame buffer. Then, the contents of the frame buffer are transmitted to a display controller for display on a display device.

The graphics processing pipeline 1000 is an abstract flow diagram of the processing steps implemented to generate 2D computer-generated images from 3D geometry data. As is well-known, pipeline architectures may perform long latency operations more efficiently by splitting up the operation into a plurality of stages, where the output of each stage is coupled to the input of the next successive stage. Thus, the graphics processing pipeline 1000 receives input data 601 that is transmitted from one stage to the next stage of the graphics processing pipeline 1000 to generate output data 1002. In an embodiment, the graphics processing pipeline 1000 may represent a graphics processing pipeline defined by the OpenGL® API. As an option, the graphics processing pipeline 1000 may be implemented in the context of the functionality and architecture of the previous Figures and/or any subsequent Figure(s).

As shown in FIG. 10, the graphics processing pipeline 1000 comprises a pipeline architecture that includes a number of stages. The stages include, but are not limited to, a data assembly 1004 stage, a vertex shading 1006 stage, a primitive assembly 1008 stage, a geometry shading 1010 stage, a viewport SCC 1012 stage, a rasterization 1014 stage, a fragment shading 1016 stage, and a raster operations 1018 stage. In an embodiment, the input data 1020 comprises commands that configure the processing units to implement the stages of the graphics processing pipeline 1000 and geometric primitives (e.g., points, lines, triangles, quads, triangle strips or fans, etc.) to be processed by the stages. The output data 1002 may comprise pixel data (e.g., color data) that is copied into a frame buffer or other type of surface data structure in a memory.

The data assembly 1004 stage receives the input data 1020 that specifies vertex data for high-order surfaces, primitives, or the like. The data assembly 1004 stage collects the vertex data in a temporary storage or queue, such as by receiving a command from the host processor that includes a pointer to a buffer in memory and reading the vertex data from the buffer. The vertex data is then transmitted to the vertex shading 1006 stage for processing.

The vertex shading 1006 stage processes vertex data by performing a set of operations (e.g., a vertex shader or a program) once for each of the vertices. Vertices may be, e.g., specified as a 4-coordinate vector (e.g., <x, y, z, w>) associated with one or more vertex attributes (e.g., color, texture coordinates, surface normal, etc.). The vertex shading 1006 stage may manipulate individual vertex attributes such as position, color, texture coordinates, and the like. In other words, the vertex shading 1006 stage performs operations on the vertex coordinates or other vertex attributes associated with a vertex. Such operations commonly including lighting operations (e.g., modifying color attributes for a vertex) and transformation operations (e.g., modifying the coordinate space for a vertex). For example, vertices may be specified using coordinates in an object-coordinate space, which are transformed by multiplying the coordinates by a matrix that translates the coordinates from the object-coordinate space into a world space or a normalized-device-coordinate (NCD) space. The vertex shading 1006 stage generates transformed vertex data that is transmitted to the primitive assembly 1008 stage.

The primitive assembly 1008 stage collects vertices output by the vertex shading 1006 stage and groups the vertices into geometric primitives for processing by the geometry shading 1010 stage. For example, the primitive assembly 1008 stage may be configured to group every three consecutive vertices as a geometric primitive (e.g., a triangle) for transmission to the geometry shading 1010 stage. In some embodiments, specific vertices may be reused for consecutive geometric primitives (e.g., two consecutive triangles in a triangle strip may share two vertices). The primitive assembly 1008 stage transmits geometric primitives (e.g., a collection of associated vertices) to the geometry shading 1010 stage.

The geometry shading 1010 stage processes geometric primitives by performing a set of operations (e.g., a geometry shader or program) on the geometric primitives. Tessellation operations may generate one or more geometric primitives from each geometric primitive. In other words, the geometry shading 1010 stage may subdivide each geometric primitive into a finer mesh of two or more geometric primitives for processing by the rest of the graphics processing pipeline 1000. The geometry shading 1010 stage transmits geometric primitives to the viewport SCC 1012 stage.

In an embodiment, the graphics processing pipeline 1000 may operate within a streaming multiprocessor and the vertex shading 1006 stage, the primitive assembly 1008 stage, the geometry shading 1010 stage, the fragment shading 1016 stage, and/or hardware/software associated therewith, may sequentially perform processing operations. Once the sequential processing operations are complete, in an embodiment, the viewport SCC 1012 stage may utilize the data. In an embodiment, primitive data processed by one or more of the stages in the graphics processing pipeline 1000 may be written to a cache (e.g. L1 cache, a vertex cache, etc.). In this case, in an embodiment, the viewport SCC 1012 stage may access the data in the cache. In an embodiment, the viewport SCC 1012 stage and the rasterization 1014 stage are implemented as fixed function circuitry.

The viewport SCC 1012 stage performs viewport scaling, culling, and clipping of the geometric primitives. Each surface being rendered to is associated with an abstract camera position. The camera position represents a location of a viewer looking at the scene and defines a viewing frustum that encloses the objects of the scene. The viewing frustum may include a viewing plane, a rear plane, and four clipping planes. Any geometric primitive entirely outside of the viewing frustum may be culled (e.g., discarded) because the geometric primitive will not contribute to the final rendered scene. Any geometric primitive that is partially inside the viewing frustum and partially outside the viewing frustum may be clipped (e.g., transformed into a new geometric primitive that is enclosed within the viewing frustum. Furthermore, geometric primitives may each be scaled based on a depth of the viewing frustum. All potentially visible geometric primitives are then transmitted to the rasterization 1014 stage.

The rasterization 1014 stage converts the 3D geometric primitives into 2D fragments (e.g. capable of being utilized for display, etc.). The rasterization 1014 stage may be configured to utilize the vertices of the geometric primitives to setup a set of plane equations from which various attributes can be interpolated. The rasterization 1014 stage may also compute a coverage mask for a plurality of pixels that indicates whether one or more sample locations for the pixel intercept the geometric primitive. In an embodiment, z-testing may also be performed to determine if the geometric primitive is occluded by other geometric primitives that have already been rasterized. The rasterization 1014 stage generates fragment data (e.g., interpolated vertex attributes associated with a particular sample location for each covered pixel) that are transmitted to the fragment shading 1016 stage.

The fragment shading 1016 stage processes fragment data by performing a set of operations (e.g., a fragment shader or a program) on each of the fragments. The fragment shading 1016 stage may generate pixel data (e.g., color values) for the fragment such as by performing lighting operations or sampling texture maps using interpolated texture coordinates for the fragment. The fragment shading 1016 stage generates pixel data that is transmitted to the raster operations 1018 stage.

The raster operations 1018 stage may perform various operations on the pixel data such as performing alpha tests, stencil tests, and blending the pixel data with other pixel data corresponding to other fragments associated with the pixel. When the raster operations 1018 stage has finished processing the pixel data (e.g., the output data 1002), the pixel data may be written to a render target such as a frame buffer, a color buffer, or the like.

It will be appreciated that one or more additional stages may be included in the graphics processing pipeline 1000 in addition to or in lieu of one or more of the stages described above. Various implementations of the abstract graphics processing pipeline may implement different stages. Furthermore, one or more of the stages described above may be excluded from the graphics processing pipeline in some embodiments (such as the geometry shading 1010 stage). Other types of graphics processing pipelines are contemplated as being within the scope of the present disclosure. Furthermore, any of the stages of the graphics processing pipeline 1000 may be implemented by one or more dedicated hardware units within a graphics processor such as parallel processing unit 402. Other stages of the graphics processing pipeline 1000 may be implemented by programmable hardware units such as the streaming multiprocessor 700 of the parallel processing unit 402.

The graphics processing pipeline 1000 may be implemented via an application executed by a host processor, such as a CPU. In an embodiment, a device driver may implement an application programming interface (API) that defines various functions that can be utilized by an application in order to generate graphical data for display. The device driver is a software program that includes a plurality of instructions that control the operation of the parallel processing unit 402. The API provides an abstraction for a programmer that lets a programmer utilize specialized graphics hardware, such as the parallel processing unit 402, to generate the graphical data without requiring the programmer to utilize the specific instruction set for the parallel processing unit 402. The application may include an API call that is routed to the device driver for the parallel processing unit 402. The device driver interprets the API call and performs various operations to respond to the API call. In some instances, the device driver may perform operations by executing instructions on the CPU. In other instances, the device driver may perform operations, at least in part, by launching operations on the parallel processing unit 402 utilizing an input/output interface between the CPU and the parallel processing unit 402. In an embodiment, the device driver is configured to implement the graphics processing pipeline 1000 utilizing the hardware of the parallel processing unit 402.

Various programs may be executed within the parallel processing unit 402 in order to implement the various stages of the graphics processing pipeline 1000. For example, the device driver may launch a kernel on the parallel processing unit 402 to perform the vertex shading 1006 stage on one streaming multiprocessor 700 (or multiple streaming multiprocessor 700 modules). The device driver (or the initial kernel executed by the parallel processing unit 402) may also launch other kernels on the parallel processing unit 402 to perform other stages of the graphics processing pipeline 1000, such as the geometry shading 1010 stage and the fragment shading 1016 stage. In addition, some of the stages of the graphics processing pipeline 1000 may be implemented on fixed unit hardware such as a rasterizer or a data assembler implemented within the parallel processing unit 402. It will be appreciated that results from one kernel may be processed by one or more intervening fixed function hardware units before being processed by a subsequent kernel on a streaming multiprocessor 700.

### LISTING OF DRAWING ELEMENTS

100 routine
102 done block
104 block
106 block
108 block
110 block
302 convolutional neural network layer
304 optical physics biasing layers
306 transpose convolutional neural network layer
308 cost function
402 parallel processing unit
404 I/O unit
406 front-end unit
408 scheduler unit
410 work distribution unit
412 hub
414 crossbar
416 NVLink
418 interconnect
420 memory
500 general processing cluster
502 pipeline manager
504 pre-raster operations unit
506 raster engine
508 work distribution crossbar
510 memory management unit
512 data processing cluster
514 primitive engine
516 M-pipe controller
600 memory partition unit
602 raster operations unit
604 level two cache
606 memory interface
700 streaming multiprocessor
702 instruction cache
704 scheduler unit
706 register file
708 core
710 special function unit
712 load/store unit
714 interconnect network
716 shared memory/L1 cache
718 dispatch
800 processing system
802 central processing unit
804 switch
806 parallel processing module
900 exemplary processing system
902 communications bus
904 main memory
906 input devices
908 display devices
910 network interface
1000 graphics processing pipeline
1002 output data
1004 data assembly
1006 vertex shading
1008 primitive assembly
1010 geometry shading
1012 viewport SCC
1014 rasterization
1016 fragment shading
1018 raster operations
1020 input data

Various functional operations described herein may be implemented in logic that is referred to using a noun or noun phrase reflecting said operation or function. For example, an association operation may be carried out by an “associator” or “correlator”. Likewise, switching may be carried out by a “switch”, selection by a “selector”, and so on. “Logic” refers to machine memory circuits and non-transitory machine readable media comprising machine-executable instructions (software and firmware), and/or circuitry (hardware) which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter). Logic symbols in the drawings should be understood to have their ordinary interpretation in the art in terms of functionality and various structures that may be utilized for their implementation, unless otherwise indicated.

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “credit distribution circuit configured to distribute credits to a plurality of processor cores” is intended to cover, for example, an integrated circuit that has circuitry that performs this function during operation, even if the integrated circuit in question is not currently being used (e.g., a power supply is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function, although it may be “configurable to” perform that function after programming.

Reciting in the appended claims that a structure is “configured to” perform one or more tasks is expressly intended not to invoke 35 U.S.C. § 112(f) for that claim element. Accordingly, claims in this application that do not otherwise include the “means for” [performing a function] construct should not be interpreted under 35 U.S.C § 112(f).

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

As used herein, the phrase “in response to” describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase “perform A in response to B.” This phrase specifies that B is a factor that triggers the performance of A. This phrase does not foreclose that performing A may also be in response to some other factor, such as C. This phrase is also intended to cover an embodiment in which A is performed solely in response to B.

As used herein, the terms “first,” “second,” etc. are used as labels for nouns that they precede, and do not imply any type of ordering (e.g., spatial, temporal, logical, etc.), unless stated otherwise. For example, in a register file having eight registers, the terms “first register” and “second register” can be used to refer to any two of the eight registers, and not, for example, just logical registers 0 and 1.

When used in the claims, the term “or” is used as an inclusive or and not as an exclusive or. For example, the phrase “at least one of x, y, or z” means any one of x, y, and z, as well as any combination thereof.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

The subject matter of the present disclosure is described with specificity herein to meet statutory requirements. However, the description itself is not intended to limit the scope of this disclosure. Rather, the inventors have contemplated that the claimed subject matter might also be embodied in other ways, to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described.

Having thus described illustrative embodiments in detail, it will be apparent that modifications and variations are possible without departing from the scope of the invention as claimed. The scope of inventive subject matter is not limited to the depicted embodiments but is rather set forth in the following Claims.

What is claimed is:

1. A system comprising:
one or more data processors; and
logic to:
transform a mask image into a plurality of light intensity feature maps;
weight the light intensity feature maps with lithographic optical physics bias to generate a coarse aerial image; and
transform the coarse aerial image through a first neural network to generate a lithographic aerial image.

2. The system of claim 1, wherein the mask image is transformed through a second neural network into the plurality of light intensity feature maps.

3. The system of claim 2, wherein the second neural network comprises at least one convolutional layer.

4. The system of claim 2, wherein the light intensity feature maps are transformed through a third neural network into the coarse aerial image.

5. The system of claim 4, further configured to apply a cost function to the generated lithographic aerial image to train parameters of the first neural network, the second neural network, and the third neural network.

6. The system of claim 1, wherein the plurality of light intensity feature maps are weighted with the lithographic optical physics bias in the frequency domain.

7. The system of claim 1, wherein the first neural network comprises at least one convolutional layer.

8. A lithographic aerial image generator comprising:
a first network stage configured to transform a first mask image having a first feature resolution into a plurality of light intensity feature maps each at a second feature resolution lower than the first feature resolution;
a second network stage configured to transform the light intensity feature maps into a coarse aerial image comprising lithographic optical physics bias; and
a third network stage configured to transform the coarse aerial image into a lithographic aerial image at the first feature resolution.

9. The lithographic aerial image generator of claim 8, wherein the first network stage comprises one or more neural network convolutional layers.

10. The lithographic aerial image generator of claim 9, wherein the first network stage comprises a single convolutional neural network layer.

11. The lithographic aerial image generator of claim 8, wherein the second network stage is configured to perform a Fast Fourier Transform on the plurality of light intensity feature maps.

12. The lithographic aerial image generator of claim 8, wherein the second network stage is configured to perform a Hadamard multiplication of the light intensity feature maps and trainable weights.

13. The lithographic aerial image generator of claim 8, wherein the third network stage comprises one or more neural network layers.

14. The lithographic aerial image generator of claim 13, wherein the third network stage comprises one or more transposed convolutional neural network layers.

15. The lithographic aerial image generator of claim 8, wherein each of the network stages comprises trainable lithographic optical physics bias weights.

16. The lithographic aerial image generator of claim 15, further configured to apply a cost function to the lithographic aerial image.

17. The lithographic aerial image generator of claim 16, further configured such that outputs of the cost function are applied to evolve weights in layers of each of the network stages.

18. A process to generate a lithographic aerial image, the process comprising:
transforming an image of a circuit mask through first neural network layers into a plurality of light intensity feature maps;
weighting the light intensity feature maps in second neural network layers with lithographic optical physics bias to generate a coarse aerial image; and
transforming the coarse aerial image through a third neural network to generate the lithographic aerial image.

19. The process of claim 18, wherein the plurality of light intensity feature maps are weighted with the lithographic optical physics bias in the frequency domain.

20. The process of claim 18, wherein the first neural network generates the plurality of light intensity feature maps at a lower feature resolution than a resolution of the image of the circuit mask.
